(19) United States
(12) Patent Application Publication
(10) Pub. No.: US 2016/0227647 A1
(43) Pub. Date: Aug. 4, 2016

(54) COATED FILMS FOR CIRCUIT BOARDS

(71) Applicant: SAINT-GOBAIN PERFORMANCE PLASTICS CORPORATION, Solon, OH (US)

(72) Inventors: Philip C. Guy, Williamstown, MA (US); Jiezhu Jin, Melbourne, FL (US); Kevin M. Manchester, Rexford, NY (US); Deirdre M. Zammit, Weston, MA (US)

(21) Appl. No.: 14/984,976

(22) Filed: Dec. 30, 2015

Related U.S. Application Data
(60) Provisional application No. 62/098,934, filed on Dec. 31, 2014.

(51) Int. Cl. H05K 1/03; C09D 129/10; C09D 127/18; C09D 123/28

(52) U.S. Cl. CPC H05K 1/0366; C09D 123/283; C09D 129/10; C09D 127/18

(57) ABSTRACT

The present disclosure is directed to composite films, such as subcomponents of a circuit board assembly including a non-meltprocessable fluoropolymer layer and a melt processable fluoropolymer layer having an average thickness in a range of from 0.1 microns to 20 microns. When included within a printed circuit board, the composite can exhibit greater resistance to delamination.

### CROSS-REFERENCE TO RELATED APPLICATION(S)

This application claims priority under 35 U.S.C. §119(e) to U.S. Patent Application No. 62/098,934 entitled “COATED FILMS FOR CIRCUIT B,” by Philip C. Guy, et al., filed Dec. 31, 2014, which is assigned to the current assignee hereof and incorporated herein by reference in its entirety.

### FIELD OF THE DISCLOSURE

The present disclosure relates to coated films for a circuit board assembly, and more particularly to, fluoropolymer coated fluoropolymer films for a circuit board assembly.

### RELATED ART

During the fabrication of copper clad laminates for high frequency circuit boards, multiple layers of PTFE films, PTFE coated fiberglass, melt processable fluoropolymer films (e.g. PFA, FEP), and/or copper foil are used. Traditionally, separate films are produced and the entire stack is laminated at high temperatures to permanently attach the layers within the composite. These films suffer from delamination failures due to the inherently poor adhesion of the PTFE films.

Accordingly, the industry is in need of a composite structure that can be used a printed circuit board subcomponent that reduces the risk of delamination while maintaining desired performances.

### BRIEF DESCRIPTION OF THE DRAWINGS

Embodiments are illustrated by way of example and are not limited in the accompanying figures.

FIG. 1 includes an illustration of a composite according to one embodiment of the present disclosure.

FIG. 2 includes an illustration of a printed circuit board according to one embodiments of the present disclosure.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the fluoropolymer arts.

The present disclosure is directed to non-meltprocessed films having a fluoropolymer coating. For example, the present inventors surprisingly discovered that by incorporating a fluoropolymer coating layer on a non-meltprocessed film, improved adhesion and bondability can be obtained when a circuit board stack is formed with the coated film. The concepts are better understood in view of the embodiments described below that illustrate and do not limit the scope of the present invention

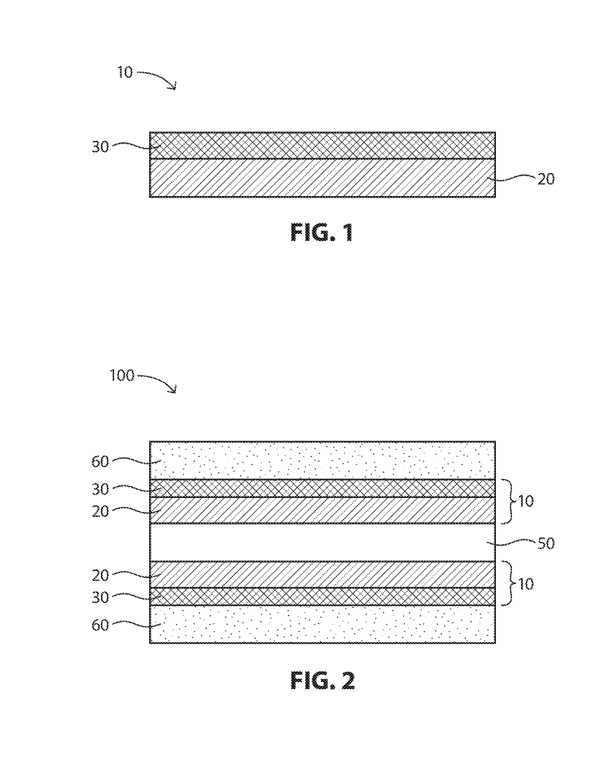

Referring now to FIG. 1, in certain embodiments, a composite film 10 can include a non-meltprocessable fluoropolymer layer 20 and a fluoropolymer coating layer 30. As illustrated in FIG. 1, the fluoropolymer coating layer 30 can be directly adjacent the non-meltprocessable fluoropolymer layer 20. In other embodiments, any additional number of layers or layer sequencing can be used.

The non-meltprocessable fluoropolymer layer 20 can be include or even consist essentially of a non-meltprocessable fluoropolymer.

As used herein, the phrase “non-meltprocessable fluoropolymer refers to a fluoropolymer which can not be processed by traditional melt processing equipment.

Examples of non-meltprocessable fluoropolymers include PTFE. In particular embodiments, the non-meltprocessable fluoropolymer layer 20 can include or even consist essentially of PTFE. In very particular embodiments, the non-meltprocessable fluoropolymer layer 20 can include or even consist essentially of homopolymer PTFE. In further very particular embodiments, the non-meltprocessable fluoropolymer layer 20 can include or even consist essentially of a virgin PTFE.

In certain embodiments, the non-meltprocessable fluoropolymer layer 20 can further include a filler in addition to the non-meltprocessable fluoropolymer.

In certain embodiments, when a filler is present in the non-meltprocessable fluoropolymer layer 20, the filler can be present in an amount of at least about 1 wt. %, at least about 5 wt. %, or even at least about 10 wt. % based on the total weight of the non-meltprocessable fluoropolymer layer 20. In further embodiments, the filler can be present in an amount of no greater than about 90 wt. %, no greater than about 80 wt. %, or even no greater than about 70 wt. % based on the total weight of the non-meltprocessable fluoropolymer layer 20. Moreover, the filler can be present within a range of any of the minimum and maximums provided above, such as in a range of from about 10 wt. % to about 80 wt. % based on the total weight of the non-meltprocessable fluoropolymer layer 20.

In certain embodiments, the non-meltprocessable fluoropolymer layer 20 can have a desired thickness. For example, in certain embodiments, the non-meltprocessable fluoropolymer layer can have a thickness of at least about 0.001 mm, at least about 0.01 mm, at least about 0.1 mm, or even at least about 1 mm. In further embodiments, in certain embodiments, the non-meltprocessable fluoropolymer layer can have a thickness of no greater than about 100 mm, no greater than about 50 mm, or even no greater than about 10 mm Moreover, in certain embodiments, the non-meltprocessable fluoropolymer layer can have a thickness in a range of any of the minimum and maximums provided above, such as in a range of from about 0.001 mm to about 50 mm.

The non-meltprocessable fluoropolymer layer 20 can also be described in terms of its surface energy. In certain embodiments, the non-meltprocessable fluoropolymer layer 20 can have a surface energy of no greater than about 24 dynes/cm, no greater than about 23 dynes/cm, no greater than about 22 dynes/cm, no greater than about 21 dynes/cm, or even no greater than about 20 dynes/cm.

A particular advantage of certain embodiments of the present disclosure is the ability to form a coated composite with a non-meltprocessable fluoropolymer layer having a low surface energy. For example, traditionally, it was very difficult to form coatings on low-surface energy films, such as virgin PTFE films. In contrast, the present inventors have developed a novel methodology to create composites incorporating such low-surface energy layers.

Referring again to FIG. 1, the coated film 10 can further include a fluoropolymer layer 30. In particular embodiments, the fluoropolymer layer 30 can be a coating layer. As used herein, the phrase “coating layer” refers to a layer that can be applied by spraying, dipping, knife coating, roll coating, or the like, and is contrasted with a preformed film that is laminated to an adjacent layer.

In certain embodiments, the fluoropolymer coating can contain or even consist essentially of a melt processable fluoropolymer. As used herein, the phrase “melt-processable fluoropolymer” refers to a fluoropolymer which can be processed by traditional melt processing methods.

The fluoropolymer coating layer 30 can have a desirable thickness. In particular embodiments, the fluoropolymer coating can have a low thickness. For example, in certain embodiments, the fluoropolymer coating can have a thickness of no greater than about 20 microns, no greater than about 18 microns, no greater than about 16 microns, no greater than about 14 microns, no greater than about 12 microns, no greater than about 10 microns, no greater than about 8 microns, or even no greater than about 6 microns. In further embodiments, the fluoropolymer coating can have a thickness of at least about 0.1 microns, at least about 0.2 microns, at least about 0.5 microns, or even at least about 1 micron. In still further embodiments, the fluoropolymer coating can have a thickness in a range of any of the minimum and maximums provided above, such as in a range of from about 0.1 microns to about 18 microns, or even about 0.5 microns to about 8 microns.

A particular advantage of certain embodiments of the present disclosure is the formation of a thin melt processable fluoropolymer layer atop a non-meltprocessable fluoropolymer layer. Traditional techniques to meet stringent industry demands required laminating a preformed meltprocessable film to a non-meltprocessable fluoropolymer layer, which required high laminating temperatures. Such techniques limited the ability to create thin meltprocessable fluoropolymer layers atop non-meltprocessable fluoropolymer layers as preforming such a meltprocessable fluoropolymer film was limited to relatively high thicknesses, such as greater than about 20 microns.

In certain embodiments, the fluoropolymer layer can be described by the presence of and density of microcracks. Microcracks are inherent formations that can occur when coating a meltprocessable fluoropolymer layer described herein. The presence and density of microcracks can be a structural characteristics that distinguishes a fluoropolymer coating layer versus a laminated fluoropolymer film layer. Accordingly, in certain embodiments, the meltprocessable fluoropolymer layer can include microcracks.

In certain embodiments, the meltprocessable fluoropolymer layer can include or even consist essentially of a meltprocessable fluoropolymer selected from fluorinated ethylene propylene copolymer (FEP), a copolymer of tetrafluoroethylene and perfluoropropyl vinyl ether (PFA), a copolymer of tetrafluoroethylene and perfluoromethyl vinyl ether (MFA), a copolymer of ethylene and tetrafluoroethylene (ETFE), a copolymer of ethylene and chlorotrifluoroethylene (ECTFE), polychlorotrifluoroethylene (PCTFE), poly vinylidene fluoride (PVDF), a terpolymer including tetrafluoroethylene, hexafluoropropylene, and vinylidenefluoride (THV), or combinations thereof. In particular embodiments, the meltprocessable fluoropolymer layer can include or even consist essentially of a meltprocessable fluoropolymer selected from perfluoroalkyl-ether copolymer (PFA) or tetrafluoroethylene-hexafluoropropylene copolymer (FEP), or combinations thereof.

In certain embodiments, the meltprocessable fluoropolymer layer can be cured after coating onto the fluoropolymer film layer. Accordingly, the composite film can include a cured meltprocessable fluoropolymer layer forming an outer surface of the composite film.

In certain embodiments, the meltprocessable fluoropolymer layer can have a surface treatment applied on the major surface opposite the non-meltprocessable fluoropolymer layer. The surface treatment can be adapted to improve the adhesion of the cured meltprocessable fluoropolymer layer to an additional layer, such as an additional layer of a circuit board assembly. In particular embodiments, the surface treatment can include a C-treatment. In very particular embodiments, the surface treatment can be adapted to increase the surface roughness of an outer surface of the melt processable fluoropolymer layer.

In certain embodiments, the composite film can consist essentially of the non-meltprocessable fluoropolymer layer and the meltprocessable fluoropolymer layer.

In certain embodiments, the composite film can be produced and wound into a roll. When unwound, the roll of the composite film can have a long continuous length. When in rolled form, it is to be understood that the meltprocessable fluoropolymer coating layer is in cured form.

Another aspect of the present disclosure is directed to a circuit board assembly that includes the composite film described herein as a circuit board assembly subcomponent. For example, referring to FIG. 2 which illustrates a basic example of one type of circuit board assembly 100, can include the coated film 10 as described herein; a metal foil layer 60; and a reinforced fluoropolymer layer 50. In particular embodiments, the reinforced fluoropolymer layer can include a fiberglass reinforced PTFE. It is to be understood that any number of additional or less layers can be included in a circuit board assembly according to the present disclosure, and is not limited in any way to the exemplary embodiment illustrated in FIG. 2. Further, in particular embodiments, the coated film 10 is cured before lamination with the other layers within the circuit board assembly 100.

The composite film described herein can be particularly useful as a subcomponent of a circuit board assembly, such as a printed circuit board assembly (PCB). In very specific embodiments, the composite film described herein can be a subcomponent of a high frequency circuit board. In further very specific embodiments, the composite film described herein can be a subcomponent of a copper clad high frequency circuit board.

Another aspect of the present disclosure is directed to a method of forming a printed circuit board subcomponent. In general, the method can include providing a non-meltprocessable fluoropolymer sheet; coating the non-meltprocessable fluoropolymer sheet with composition comprising a meltprocessable fluoropolymer; and curing the melt processable fluoropolymer coating. It is to be understood that embodiments of the method described herein includes providing and/or forming the respective layers in accordance with any of the characteristics described herein. For example, it is to be understood that providing a non-meltprocessable fluoropolymer sheet can include a non-meltprocessable fluoropolymer sheet according to any of the embodiments described herein.

In certain embodiments, the step of providing a non-meltprocessable fluoropolymer sheet can include forming the non-meltprocessable fluoropolymer sheet. For example, the non-meltprocessable fluoropolymer sheet can be formed by casting, skiving, and/or paste extrusion.

In certain embodiments, the step of coating the non-meltprocessable fluoropolymer sheet with a composition comprising a meltprocessable fluoropolymer can include dip coating, spray coating, roll coating, knife coating, or combinations thereof. In particular embodiments, the meltprocessable fluoropolymer can not be formed separately from the non-meltprocessable fluoropolymer sheet. For example, in certain embodiments, the meltprocessable fluoropolymer layer can not be formed as a standalone sheet material and laminated to the non-meltprocessable fluoropolymer sheet.

In certain embodiments, the method can further include applying a surface treatment to the cured meltprocessable fluoropolymer layer. For example, in certain embodiments, the surface treatment can be adapted to improve the adhesion of the meltprocessable fluoropolymer layer with adjacent layers in a printed circuit board assembly. In particular embodiments, the surface treatment can include C-treating.

In certain embodiments, the step of curing the meltprocessable fluoropolymer composition comprises thermally curing the meltprocessable fluoropolymer composition. For example, the melt processable fluoropolymers can be cured at a temperature in a range of from about 500 degrees Fahrenheit to 700 degrees Fahrenheit, depending on the specific melt processable fluoropolymer that is employed.

In particular embodiments, the step of curing the meltprocessable fluoropolymer composition can include curing in a horizontal oven.

Yet another aspect of the present disclosure is directed to a method of forming a printed circuit board. In general, the method of forming a printed circuit board can include providing the coated fluoropolymer film described herein; providing additional layers of a printed circuit board assembly; and laminating the layers together to form a printed circuit board.

In certain embodiments, the step of providing additional layers of a printed circuit board assembly can include providing a metal foil sheet. Further, in certain embodiments, the step of providing additional layers of a printed circuit board assembly can include providing a reinforced PTFE sheet.

In certain embodiments, the step of curing the meltprocessable fluoropolymer layer can occur before laminating the printed circuit board layering together.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the items as listed below.

Item 1. A composite film comprising:
a. a first polymeric layer comprising a non-meltprocessable polymer; and
b. a meltprocessable fluoropolymer layer having an average thickness in a range of 0.1 microns to 20 microns.

Item 2. A subcomponent of a circuit board assembly comprising:
a. a cured composite film comprising:
   i. a first polymeric layer consisting essentially of a non-meltprocessable PTFE polymer; and
   ii. a melt processable fluoropolymer layer having an average thickness in a range of about 0.1 microns to about 10 microns;
b. wherein the melt processable fluoropolymer layer comprises a first outer surface and a second outer surface, wherein the first outer surface is adjacent the first polymer layer and the second outer surface is opposite the first outer surface, and wherein the second outer surface comprises a surface treatment adapted to improve the adhesion of the melt processable fluoropolymer layer to a metal foil.

Item 3. The composite film or subcomponent of any one of the preceding items, wherein the first polymeric layer comprises a non-meltprocessable polymer.

Item 4. The composite film or subcomponent of any one of the preceding items, wherein the first polymeric layer comprises a non-meltprocessable polymer comprising PTFE.

Item 5. The composite film or subcomponent of any one of the preceding items, wherein the first polymeric layer comprises homopolymer PTFE.

Item 6. The composite film or subcomponent of any one of the preceding items, wherein the first polymeric layer comprises a non-meltprocessable PTFE.

Item 7. The composite film or subcomponent of any one of the preceding items, wherein the first polymeric layer is a virgin PTFE layer.

Item 8. The composite film or subcomponent of any one of the preceding items, wherein the first polymeric layer comprises a filler.

Item 9. The composite film or subcomponent of any one of the preceding items, wherein the first polymeric layer comprises a cast or skived PTFE layer.

Item 10. The composite film or subcomponent of any one of the preceding items, wherein the first polymeric layer has a surface energy of no greater than 24 about dynes/cm, no greater than about 23 dynes/cm, no greater than about 22 dynes/cm, no greater than about 21 dynes/cm, or even no greater than about 20 dynes/cm.

Item 11. The composite film or subcomponent of any one of the preceding items, wherein the meltprocessable fluoropolymer layer has a thickness of no greater than about 20 microns, no greater than about 18 microns, no greater than about 16 microns, no greater than about 14 microns, no greater than about 12 microns, no greater than about 10 microns, no greater than about 8 microns, or even no greater than about 6 microns.

Item 12. The composite film or subcomponent of any one of the preceding items, wherein the meltprocessable fluoropolymer layer has a thickness of at least about 0.1 microns, at least about 0.2 microns, at least about 0.5 microns, or even at least about 1 micron.

Item 13. The composite film or subcomponent of any one of the preceding items, wherein the meltproces sable fluoropolymer layer has a thickness in a range of about 0.1 microns to about 18 microns, or even about 0.5 microns to about 8 microns.

Item 14. The composite film or subcomponent of any one of the preceding items, wherein the meltprocessable fluoropolymer layer is a coating layer.

Item 15. The composite film or subcomponent of any one of the preceding items, wherein the meltprocessable fluoropolymer layer comprises a meltprocessable fluoropolymer selected from perfluoroalkyl-ether copolymer (PFA) or tetrafluoroethylene-hexafluoropropylene copolymer (FEP), or combinations thereof.

Item 16. The composite film or subcomponent of any one of the preceding items, wherein the meltprocessable fluoropolymer layer comprises a meltprocessable fluoropolymer selected from fluorinated ethylene propylene copolymer (FEP), a copolymer of tetrafluoroethylene and perfluoropropyl vinyl ether (PFA), a copolymer of tetrafluoroethylene and perfluoromethyl vinyl ether (MFA), a copolymer of ethylene and tetrafluoroethylene (ETFE), a copolymer of ethylene and chlorotrifluoroethylene (ECTFE), polychlorotrifluoroethylene (PCTFE), poly vinylidene fluoride (PVDF), a terpolymer including tetrafluoroethylene, hexafluoropropylene, and vinylidenefluoride (THV), or combinations thereof.

Item 17. The composite film or subcomponent of any one of the preceding items, wherein the meltprocessable fluoropolymer layer comprises a meltprocessable fluoropolymer selected from fluorinated ethylene propylene copolymer (FEP), a copolymer of tetrafluoroethylene and perfluoropropyl vinyl ether (PFA), or combinations thereof.

Item 18. The composite film or subcomponent of any one of the preceding items, wherein the meltprocessable fluoropolymer layer is a cured layer.

Item 19. The composite film or subcomponent of any one of the preceding items, wherein the meltprocessable fluoropolymer layer comprises a surface treatment.

Item 20. The composite film or subcomponent of any one of the preceding items, wherein the meltprocessable fluoropolymer layer comprises a surface treatment adapted to promote adhesion.

Item 21. The composite film or subcomponent of any one of the preceding items, wherein the meltprocessable fluoropolymer layer comprises a surface treatment comprising C-treatment.

Item 22. The composite film or subcomponent of any one of the preceding items, wherein the meltprocessable fluoropolymer layer comprises a C-treated outer surface.

Item 23. The composite film or subcomponent of any one of the preceding items, wherein the melt processable fluoropolymer layer comprises a surface treatment adapted to increase the surface roughness of an outer surface of the melt processable fluoropolymer layer opposite the PTFE sheet.

Item 24. The composite film or subcomponent of any one of the preceding items, wherein the composite film consists essentially of the PTFE layer and the meltprocessable fluoropolymer layer.

Item 25. The composite film or subcomponent of any one of the preceding items, wherein the meltprocessable fluoropolymer layer is a cured layer

Item 26. The composite film of any one of the preceding items, wherein the composite film is adapted to be a subcomponent of a circuit board assembly.

Item 27. The composite film or subcomponent of any one of the preceding items, wherein the composite film is adapted to be a subcomponent of a copper clad composite for high frequency circuit boards.

Item 28. A subcomponent of a circuit board assembly comprising the composite film of any one of the preceding items.

Item 29. A subcomponent of a circuit board assembly comprising the composite film of any one of the preceding items.

Item 30. A printed circuit board comprising the composite film of any one of the preceding items.

Item 31. The printed circuit board of item 30, wherein the printed circuit board is a high frequency printed circuit board.

Item 32. A composite comprising:
a. a PTFE layer; and
b. a meltprocessable fluoropolymer layer having an average thickness in a range of 0.1 microns to 20 microns; and
c. a metal foil layer.

Item 33. The composite or subcomponent of any one of the preceding items, wherein the composite comprises more than one PTFE layer.

Item 34. The composite or subcomponent of any one of the preceding items, wherein the composite further comprises a reinforced PTFE layer.

Item 35. The composite or subcomponent of any one of the preceding items, wherein the composite further comprises a reinforced PTFE layer comprising a fiberglass reinforcement material.

Item 36. A method of forming a composite comprising:
a. providing a PTFE sheet;
b. coating the PTFE sheet with a meltprocessable fluoropolymer coating composition to form a meltprocessable fluoropolymer layer, wherein the meltprocessable fluoropolymer layer has an average thickness in a range of 0.1 microns to 20 microns.

Item 37. The method of any one of the preceding items, wherein providing a PTFE sheet comprises providing a PTFE sheet having a width of at least 0.5 meters, at least 1 meter, or even at least about 1.5 meters.

Item 38. The method of any one of the preceding items, wherein the method further comprises curing the meltprocessable fluoropolymer layer after coating on the PTFE sheet.

Item 39. The method of any one of the preceding items, wherein the method further comprises curing the meltprocessable fluoropolymer layer at a temperature of at least 500 degrees Fahrenheit, at least 550 degrees Fahrenheit, or even at least about 630 degrees Fahrenheit.

Item 40. The method of any one of the preceding items, wherein the method further comprises treating a major surface of the cured meltprocessable fluoropolymer layer to promote adhesion.

Item 41. The method of any one of the preceding items, wherein the method further comprises C-treating a major surface of the cured meltprocessable fluoropolymer layer to promote adhesion.

Item 42. The method of any one of the preceding items, wherein the method further comprises providing a metal foil sheet, contacting the metal foil sheet and the coated PTFE sheet such that the meltprocessable fluoropolymer coating layer is disposed between the PTFE sheet and the metal foil sheet.

Item 43. The method of item 32, wherein the method further comprises laminating, at least, the metal foil sheet and the coated PTFE sheet.

Item 44. The method of any one of the preceding items, wherein the method further comprises forming the PTFE sheet.

Item 45. The method of any one of the preceding items, wherein the method further comprises forming the PTFE sheet by a non-meltprocessable method.

Item 46. The method of any one of the preceding items, wherein the method further comprises forming the PTFE sheet by casting, skiving, or ram extrusion.

Item 47. The method of any one of the preceding items, wherein the method further comprises forming the PTFE sheet by skiving.

Item 48. The method of any one of the preceding items, wherein coating the PTFE sheet comprises spray coating, roll coating, dip coating, or any combination thereof.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A composite film comprising:
a. a first polymeric layer comprising a non-meltprocessable polymer; and
b. a meltprocessable fluoropolymer layer having an average thickness in a range of 0.1 microns to 20 microns.

2. The composite film of claim 1, wherein the first polymeric layer is a virgin PTFE layer.

3. The composite film of claim 1, wherein the first polymeric layer comprises a cast or skived PTFE layer.

4. The composite film of claim 1, wherein the first polymeric layer has a surface energy of no greater than 24 about dynes/cm.

5. The composite film of claim 1, wherein the meltprocessable fluoropolymer layer has a thickness of no greater than about 20 microns.

6. The composite film of claim 1, wherein the meltproces sable fluoropolymer layer is a coating layer.

7. The composite film of claim 1, wherein the meltproces sable fluoropolymer layer comprises a meltprocessable fluoropolymer selected from fluorinated ethylene propylene copolymer (FEP), a copolymer of tetrafluoroethylene and perfluoropropyl vinyl ether (PFA), or combinations thereof.

8. The composite film of claim 1, wherein the meltprocessable fluoropolymer layer is a cured layer.

9. A printed circuit board comprising the composite film of claim 1.

10. A composite comprising:
a. the composite film of claim 1; and
b. a metal foil layer.

11. The composite of claim 10, wherein the composite further comprises a reinforced PTFE layer comprising a fiberglass reinforcement material.

12. A subcomponent of a circuit board assembly comprising:
a. a cured composite film comprising:
i. a first polymeric layer consisting essentially of a non-meltprocessable PTFE polymer; and
ii. a melt processable fluoropolymer layer having an average thickness in a range of about 0.1 microns to about 10 microns;
b. wherein the melt processable fluoropolymer layer comprises a first outer surface and a second outer surface, wherein the first outer surface is adjacent the first polymer layer and the second outer surface is opposite the first outer surface, and wherein the second outer surface comprises a surface treatment adapted to improve the adhesion of the melt processable fluoropolymer layer to a metal foil.

13. The subcomponent of claim 12, wherein the first polymeric layer has a surface energy of no greater than 24 about dynes/cm.

14. The subcomponent of claim 12, wherein the meltprocessable fluoropolymer layer is a coating layer.

15. The subcomponent of claim 12, wherein the meltprocessable fluoropolymer layer comprises a meltprocessable fluoropolymer selected from fluorinated ethylene propylene copolymer (FEP), a copolymer of tetrafluoroethylene and perfluoropropyl vinyl ether (PFA), or combinations thereof.

16. The subcomponent of claim 12, wherein the meltprocessable fluoropolymer layer is a cured layer.

17. A method of forming a composite comprising:
a. providing a PTFE sheet;
b. coating the PTFE sheet with a meltprocessable fluoropolymer coating composition to form a meltprocessable fluoropolymer layer, wherein the meltprocessable fluoropolymer layer has an average thickness in a range of 0.1 microns to 20 microns.

18. The method of claim 17, wherein providing a PTFE sheet comprises providing a PTFE sheet having a width of at least 0.5 meters.

19. The method of claim 17, further comprising providing a metal foil sheet, contacting the metal foil sheet and the coated PTFE sheet such that the meltprocessable fluoropolymer coating layer is disposed between the PTFE sheet and the metal foil sheet.

20. The method of claim 19, wherein the method further comprises laminating, at least, the metal foil sheet and the coated PTFE sheet.
